(19) United States
(12) Patent Application Publication
(10) Pub. No.: US 2026/0368405 A1
(43) Pub. Date: Nov. 19, 2026

(54) APPARATUSES AND METHODS OF CO-SIMULATION VIA A SOCKET TO ENABLE EARLY VERIFICATION WITHOUT TANGIBLE HARDWARE

(71) Applicant: CIENA CORPORATION, Hanover, MD (US)

(72) Inventors: Tingjun Wen, Kanata (CA); Renée Warriner, Ottawa (CA); Farhad Andalibi, Ottawa (CA); Sayed Saeed Rezazadeh, Ottawa (CA); Bruce Gillespie, Ottawa (CA); Vladimir Kravets, Manotick (CA); Mohamed Yousri Mahmoud, Ottawa (CA); James Laurence Falt, Kanata (CA); Sebastien Blais, Stittsville (CA); Lukas Jakober, Ottawa (CA)

(73) Assignee: CIENA CORPORATION, Hanover, MD (US)

(21) Appl. No.: 19/209,879

(22) Filed: May 16, 2025

(51) Int. Cl. G06F 30/3308; G06F 8/30; G06F 8/40; G06F 30/327

(52) U.S. Cl. CPC G06F 30/3308; G06F 8/30; G06F 8/40; G06F 30/327

(57) ABSTRACT

Aspects of the subject disclosure may include, for example, developing code in a first environment for verifying hardware in a second environment, modifying the code via at least one socket to transform the code to a register-transfer level (RTL) model description, and simulating, using the RTL model description, the functionality of the hardware in the second environment without the hardware being physically present in the second environment, resulting in a first simulation. Other embodiments are disclosed.

### FIELD OF THE DISCLOSURE

The subject disclosure relates to apparatuses and methods of co-simulation via a socket to enable early verification without tangible hardware.

### BACKGROUND

Simulation and verification play a significant role in ensuring the proper functionality of a chip or circuit design. Engineers routinely employ simulation environments to model complex designs, validate functionality, and identify potential issues well before tangible/physical hardware prototypes become available. Traditionally, these environments have relied on established methodologies and languages to emulate the behavior of integrated circuits, offering a means to predict performance and preemptively address design flaws. Such environments support early evaluation and troubleshooting, providing a fundamental basis for subsequent hardware testing and verification practices.

In many design and verification workflows, there exists a need to establish a seamless transition between simulation models and hardware implementations. Verification engineers aim to develop processes that enable early and thorough validation of design parameters while reducing the time and resources needed during later stages of development. A goal in this area is to ensure that test cases developed in simulation can later be utilized in lab environments without extensive modifications. This objective is driven by the desire to reduce the iterative cycle between simulation and hardware bring-up, improving overall efficiency, lowering developmental costs, and enhancing the reliability of the final product design. Such unified approaches are sought to create a more coherent and streamlined verification process across various testing platforms and environments.

Despite the advancements in simulation, conventional techniques continue to face challenges that limit their effectiveness in the context of modern designs. Existing approaches often require distinct processes for modeling, simulation, and hardware testing, resulting in segmented workflows that can slow down overall project timelines. The need to manually translate or adapt test cases between different verification frameworks can introduce errors and discrepancies, undermining the accuracy of early validation efforts. Additionally, the divergence between simulation environments and physical hardware characteristics means that replicating real-world conditions is frequently cumbersome, thereby limiting the scope of testing. These challenges underscore the limitations present in established verification systems when handling the increasingly intricate requirements of modern designs.

### BRIEF DESCRIPTION OF THE DRAWINGS

Reference will now be made to the accompanying drawings, which are not necessarily drawn to scale, and wherein:

FIG. 1 is a block diagram illustrating an exemplary, non-limiting embodiment of a system for development code constructs for simulating a device under test in accordance with various aspects described herein.

FIG. 2A depicts an illustrative representation of a simulated device under test in accordance with various aspects of this disclosure.

FIG. 2B depicts an illustrative representation of an environment for testing an instance of a tangible hardware asset in accordance with various aspects of this disclosure.

FIG. 3 depicts an illustrative embodiment of a method in accordance with various aspects described herein.

FIG. 4 is a block diagram of an example, non-limiting embodiment of a computing environment in accordance with various aspects described herein.

### DETAILED DESCRIPTION

The subject disclosure describes, among other things, illustrative embodiments for facilitating simulation and testing of a circuit design using one or more sockets to port test cases generated in a developmental environment or software program. Other embodiments are described in the subject disclosure.

One or more aspects of the subject disclosure include, in whole or in part, a system comprising a processing system including a processor and a memory. The memory may store executable instructions that, when executed by the processing system, facilitate performance of operations. The operations may include: developing code in a first environment for verifying hardware in a second environment; modifying the code via at least one socket to transform the code to a register-transfer level (RTL) model description; and simulating, using the RTL model description, the functionality of the hardware in the second environment without the hardware being physically present in the second environment, resulting in a first simulation.

One or more aspects of the subject disclosure include, in whole or in part, a non-transitory machine-readable medium, comprising executable instructions that, when executed by a processing system including a processor, facilitate performance of operations. The operations may include: developing code in a first environment for verifying hardware in a second environment; modifying the code via at least one socket to transform the code to a register-transfer level (RTL) model description; and simulating, using the RTL model description, the functionality of the hardware in the second environment without the hardware being physically present in the second environment, resulting in a first simulation.

One or more aspects of the subject disclosure include, in whole or in part, a method, comprising: developing, by a processing system including a processor, code in a first environment for verifying hardware in a second environment; modifying, by the processing system, the code via at least one socket to transform the code to a register-transfer level (RTL) model description; and simulating, by the processing system and using the RTL model description, the functionality of the hardware in the second environment without the hardware being physically present in the second environment, resulting in a first simulation.

By way of introduction, it is understood and appreciated that there are differences between simulating a device under test (DUT) in a laboratory environment and performing a test on an instance of actual, physical/tangible hardware of a circuit. In many instances, and in the interest of time, it is desirable to be able to prove-out or verify the functionality of a design prior to the actual, physical/tangible hardware being available. In many instances, simulation environments do not naturally align with the operational or developmental environments/tools used in laboratory settings, leading to gaps in test coverage and potential inconsistencies in behavior. The difficulty in establishing reliable communication between simulation platforms and external testing tools can result in partial validation of important functions. Moreover, disjointed interfaces and inconsistent data representations often require a substantial reworking of test routines when moving from a simulated context/environment to actual hardware implementations. This fragmentation not only increases the risk of overlooking subtle design errors but also extends development timelines by introducing additional debugging and reiteration cycles. Aspects of this disclosure address these and other issues.

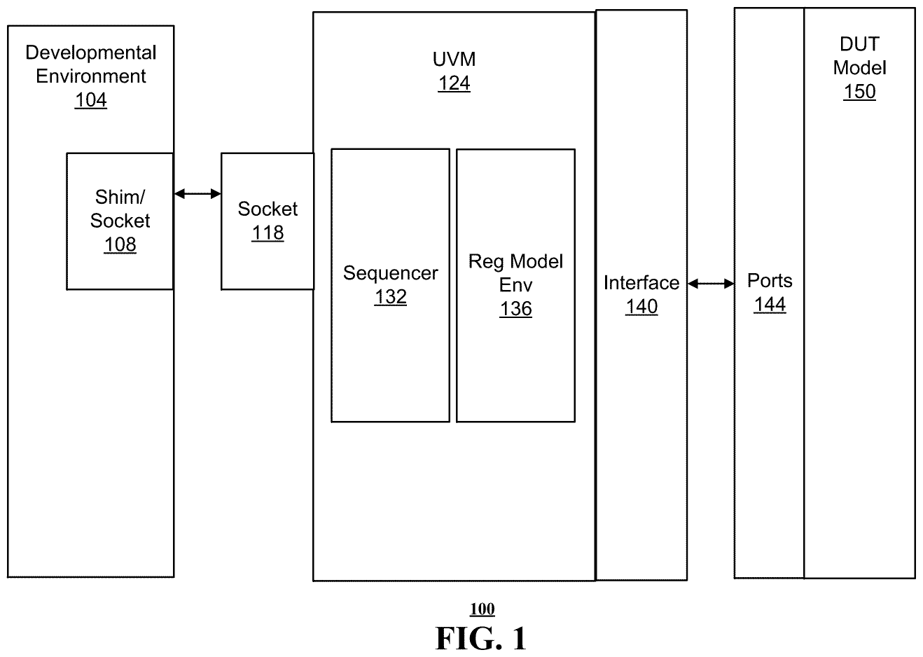

With the foregoing in mind, reference may now be made to FIG. 1, which is a block diagram illustrating an exemplary, non-limiting embodiment of a system environment 100 in accordance with various aspects described herein. The system 100 may include a number of entities, such as for example a developmental environment 104 and associated shim/socket 108, a socket 118, a universal verification methodology (UVM) environment 124 (inclusive of a sequencer 132 and a register model environment (reg model env) 136), an interface 140, ports 144, and a device under test (DUT) model 150. It should be kept in mind that the depiction of the system 100 in FIG. 1 is representative of a variant or a particular embodiment of how the various entities may be arranged as part of a practical application, with the understanding that other topologies or arrangements of the entities may be utilized in a given embodiment.

The developmental environment 104 may be indicative of an environment where test cases/stimuli can be developed to facilitate a simulation of, e.g., the DUT model 150. Various programs may be used in conjunction with the developmental environment 104. As an illustrative example, the developmental environment 104 may include MATLAB as developed/provided by MathWorks.

The shim/socket 108 may act as an intermediary between the developmental environment 104 and the UVM 124 (by way of the socket 118). To the extent that the developmental environment 104 includes MATLAB as referenced above, the shim 108 may include a MATLAB executable (MEX) shim. The shim 108 may handle a conversion of code or data structures developed in the developmental environment 104 for use in conjunction with the UVM 124 (by way of the socket 118). By using the shim 108, computationally intensive tasks may be offloaded from the developmental environment 104, which can improve the performance and efficiency of engineers interfacing to/with the developmental environment 104. Furthermore, the shim 108 may provide flexibility by allowing an engineer/user to leverage existing libraries and codebases written in other languages, expanding the functionalities and capabilities available to the engineer/user.

In some embodiments, the socket 108 and the socket 118 may be arranged/configured to communicate with one another using one or more standards, protocols, or the like. For example, and in embodiments where the developmental environment 104 is executed on a first machine (e.g., a first computing device, such as a personal or desktop computer) and the UVM 124 and the DUT model 150 are executed on a second machine (e.g., a second computing device, such as a server), the sockets 108 and 118 may be operative in accordance with the Transmission Control Protocol (TCP), the User Datagram Protocol (UDP), and/or the Internet Protocol (IP). Furthermore, the use of separate machines can enable a simulator (e.g., the UVM 124) to operate continuously. In this respect, if any variations or modifications are desired in the simulation, such variations/modifications may be incorporated as part of the developmental environment 104 without requiring a re-compilation of the simulator. The ability to avoid having to re-compile the simulator may provide significant time savings, as many modern simulations and designs result in a compilation time on the order of one hour in duration. As such, aspects of this disclosure may enable greater speed to be realized in terms of the time it takes to complete simulation or testing activities.

While not shown in FIG. 1, in some embodiments various tools or suites may be utilized to support troubleshooting or debugging the sockets 108 and 118. For example, TELNET, NETCAT and/or PYTHON may be utilized for troubleshooting or debugging purposes.

In general, the test cases developed in the developmental environment 104 may correspond to a number of get or read operations and a number of set or write operations. The shim/socket 108 and/or the socket 118 may be responsible for converting or translating those get/read and set/write operations from the language/constructs utilized by the developmental environment 104 to the language/constructs utilized by the UVM 124. In some embodiments, a socket may include a service or microservice that is capable of facilitating the conversion or translation. In some embodiments, a socket may include software code or a program to facilitate the conversion or translation.

As described above, the UVM 124 may include a sequencer 132. The sequencer 132 may be tasked with configuring the DUT model 150 and advancing the DUT model 150 through various phases of testing. The configuring of the DUT model 150 may involve a number of configuration steps, such as establishing/bringing-up a clock signal for use by the DUT model 150. The register model environment 136 may work in tandem with the sequencer 132 to facilitate configuration and testing. In particular, the register model environment 136 may allow register names to be used to facilitate programming and configuration of the DUT model 150. As one skilled in the art will appreciate, the use of register names in conjunction with the register model environment 136 may tend to be more “user-friendly” or convenient from the perspective of a user/engineer, as a user/engineer may tend to prefer to interact with the system 100 (e.g., the UVM 124) on the basis of the register names (as opposed to a (numeric) address, for example). The interface 140 and the ports 144 may serve to connect or communicatively couple the UVM 124 and the DUT model 150.

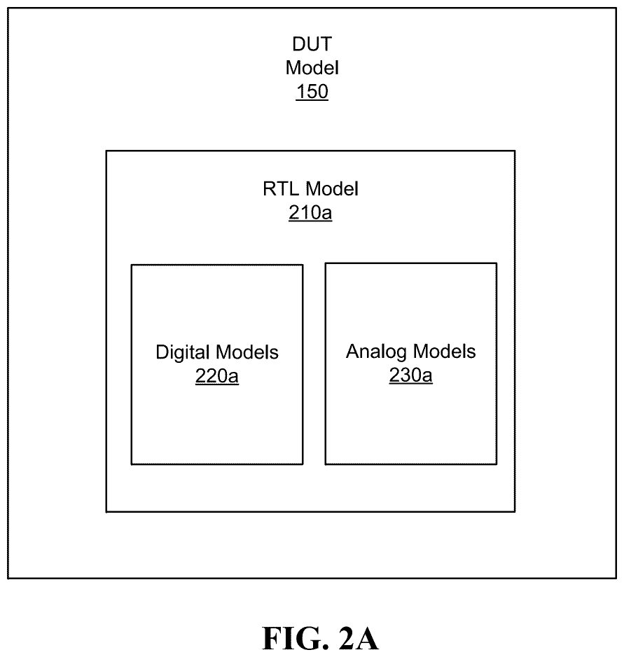

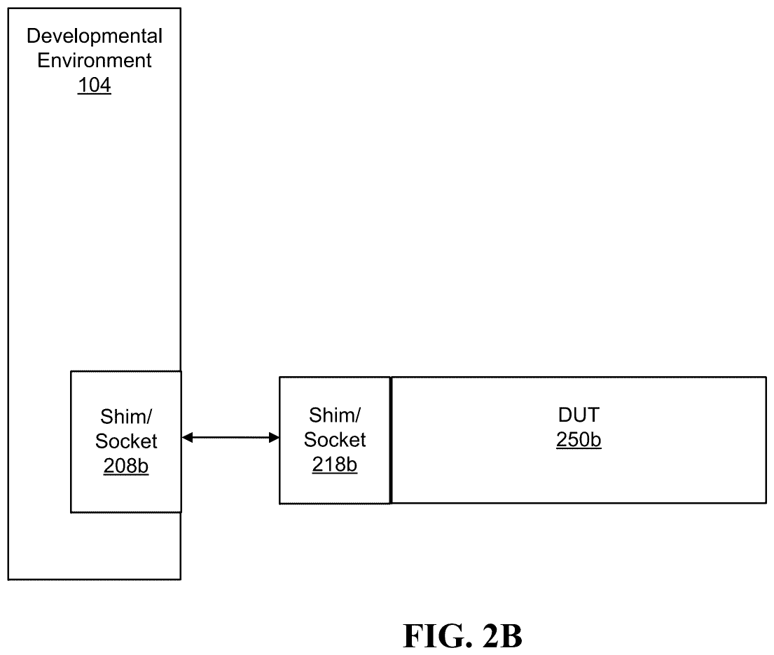

Referring now to FIG. 2A, a closer view of the DUT model 150 of FIG. 1 is shown. In particular, the DUT model 150 may be arranged to include one or more register-transfer level (RTL) model descriptions, such as for example a RTL model 210a as shown. Conventionally, the RTL model 210a may provide support for digital representations of a circuit, as fairly represented by the digital models 220a shown in FIG. 2A. However, conventionally, analog circuit models have not been well supported (e.g., very limited testing—e.g., on the order of 15%—has conventionally been available for analog circuits). In contrast, aspects of this disclosure may enhance the ability to test and simulate analog circuits (as fairly represented by the analog models 230a shown in FIG. 2A), such that testing/simulation of a circuit design afforded by aspects of this disclosure may approach 100%. This ability to accurately and (nearly) completely simulate and test a complete circuit design, including analog models 230a, in conjunction with the DUT model 150 represents a major paradigm shift in the state of the art, as substantially greater degrees of confidence are available/obtainable prior to the availability/arrival of instances of actual/physical hardware.

Referring now to FIG. 2B, the developmental environment is shown as including a shim or socket 208b that interfaces to a shim or socket 218b coupled to a DUT 250b. What is important to note in respect of FIG. 2B is that the DUT 250b may be representative of actual, tangible/physical instance of hardware corresponding to a circuit design, and the shims/sockets 208b and 218b may be responsible for interfacing the developmental environment 104 and the DUT 250b to one another. The shims/sockets 208b and 218b may be operative in accordance with one or more standards or protocols. For example, the shims/sockets 208b and 218b may adhere to UDP.

By virtue of the use of the shims/sockets 208b and 218b, any code constructs developed by/within the developmental environment 104 may be reused as between the DUT model 150 (of FIGS. 1 and 2A) and the DUT 250b. Stated differently, a user/engineer might not have to redevelop code constructs for use with the DUT 250b; the user/engineer may simply continue to reuse the code constructs developed for use with the DUT model 150. This ability to reuse the code constructs: (1) eliminates a variable that might otherwise arise/be present as between simulation involving the DUT model 150 and testing involving the DUT 250b (which can be helpful in the event of any inconsistencies or discrepancies that may exist in the behaviors/outputs of the DUT model 150 vis-à-vis the behaviors/outputs of the DUT 250b), (2) reduces complexity, and (3) reduces costs (e.g., financial investment and time) involved in the development and verification of a circuit design. In brief, the arrangements shown in FIGS. 1, 2A, and 2B allow for a seamless transition from simulation to hardware testing.

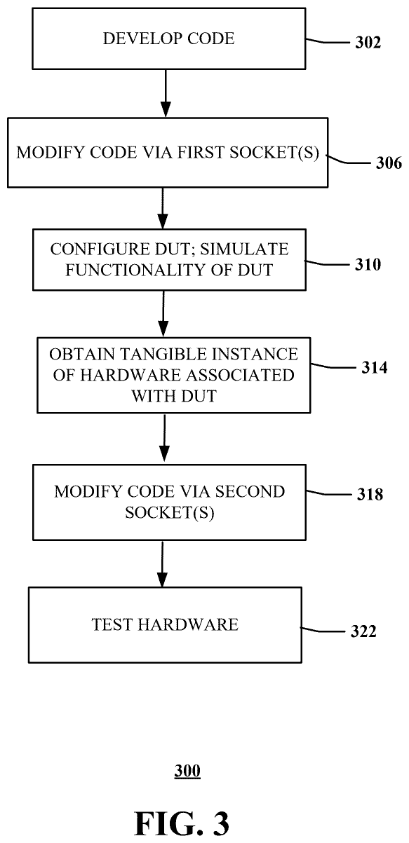

Referring now to FIG. 3, an illustrative embodiment of a method 300 in accordance with various aspects described herein is shown. The method 300 may be implemented or executed, in whole or in part, in conjunction with one or more systems, devices, and/or components, such as for example the systems, devices, and components set forth herein. In some embodiments, the method 300 may be wholly or partially implemented or executed via one or more processing systems, where each such processing system may include one or more processors. Further, in some embodiments, operations of the method 300 may be embodied as instructions that may be executed by one or more processing systems to obtain/realize the functionality associated therewith. The instructions may be stored in one or more forms and/or in respect of one or more entities, such as a memory, a transitory or non-transitory computer-readable or machine-readable medium, etc. Various operations facilitated via the method 300 are described below in relation to the blocks shown in FIG. 3. In some embodiments, one or more blocks or operations may be based on one or more other blocks or operations.

In block 302, code may be developed in a first environment (see, e.g., developmental environment 104 of FIG. 1). The code may include one or more constructs for testing functionality of a device under test (DUT), where the DUT may include hardware of a circuit design. The code may take the form of a number of get/read operations and/or set/write operations. The code may serve to configure the DUT, such as for example a clock associated with the DUT.

In block 306, the code developed as part of block 302 may be modified or transformed. For example, block 306 may involve a transformation via one or more sockets. The transformation may result in a RTL model description that may correspond to a RTL description of the DUT.

In block 310, the functionality of the DUT may be simulated. The simulation of block 310 may involve a use of the RTL model description generated as part of block 306.

In block 314, a tangible instance of the hardware associated with the DUT may be obtained. For example, block 314 may include a manufacture or fabrication of the hardware. The hardware may represent the physical manifestation of a circuit design.

In block 318, the code of block 302 may be modified or transformed using one or more sockets. The modification/transformation of block 318 may enable the code to port to the actual, tangible instance of the hardware (as obtained in block 314).

In block 322, the hardware (obtained as part of block 314) may be tested. The testing of block 322 may utilize the modified code obtained as part of block 318.

While for purposes of simplicity of explanation, the respective processes are shown and described as a series of blocks in FIG. 3, it is to be understood and appreciated that the claimed subject matter is not limited by the order of the blocks, as some blocks may occur in different orders and/or concurrently with other blocks from what is depicted and described herein. Moreover, not all illustrated blocks may be required to implement the methods described herein.

It is understood and appreciated that various ones of the blocks of the method 300 may be executed iteratively or repeatedly. For example, if the behaviors or outputs of the DUT or the actual, tangible hardware fail to conform to an expectation, it may be necessary to revise the code to simulate or test different scenarios or behaviors to attempt to identify where any potential issues may reside.

As set forth above, aspects of this disclosure provide a number of benefits relative to the conventional state of the art. For example, aspects of this disclosure may be used to interface simulation tools (e.g., UVM) to mathematical modeling tools (e.g., MATLAB). Sockets may be utilized to facilitate seamless communication and integration between the simulation tools and the modeling tools. By virtue of the use of the sockets, a co-simulation environment may be realized/obtained, whereby the simulation tools and the modeling tools may run/execute simultaneously and interact with one another as if they were part of the same integral system. The various system arrangements may enable engineers/users to have an opportunity to verify the design of a circuit (e.g., an application-specific integrated circuit [ASIC]) at an early stage of the development process. For example, an engineer may have an ability to test how the circuit will behave in real-world situations, or under real-world conditions, without needing to construct a physical prototype. Aspects of this disclosure may include or provide support for debugging and testing. For example, engineers may have an ability to send commands and data between simulations to test different scenarios and ensure that a design is functioning as intended. In brief, aspects of this disclosure provide an ability to simulate and test complex electronic circuits using software constructs, which conserves time and resources by removing the requirement for initial hardware prototypes or tangible/physical hardware assets.

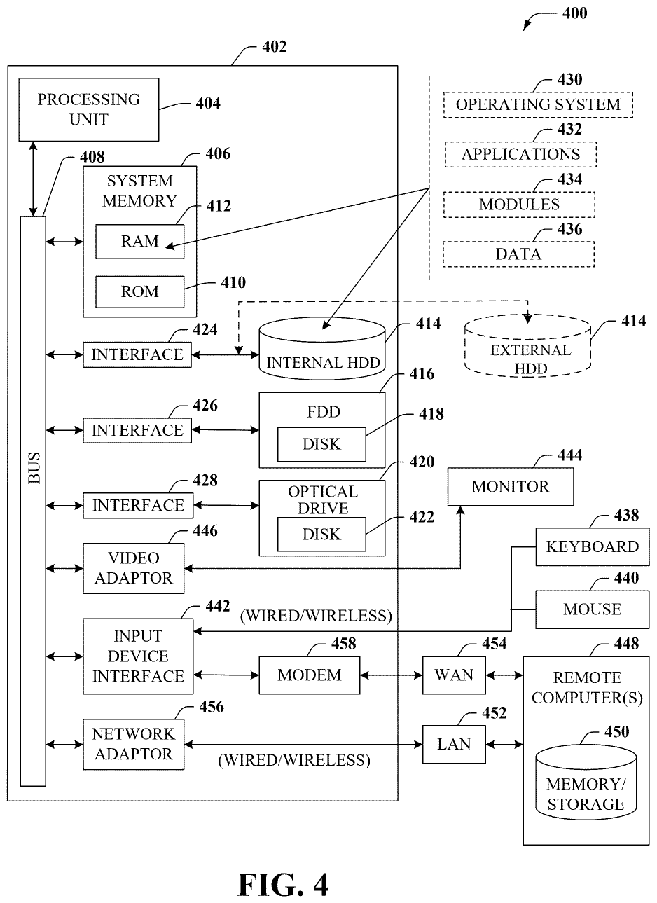

Turning now to FIG. 4, a block diagram is illustrated of a computing environment in accordance with various aspects described herein. In order to provide additional context for various embodiments of the embodiments described herein, FIG. 4 and the following discussion are intended to provide a brief, general description of a suitable computing environment 400 in which the various embodiments of the subject disclosure can be implemented. For example, the computing environment 400 can facilitate, in whole or in part, developing code in a first environment for verifying hardware in a second environment; modifying the code via at least one socket to transform the code to a register-transfer level (RTL) model description; and simulating, using the RTL model description, the functionality of the hardware in the second environment without the hardware being physically present in the second environment, resulting in a first simulation.

Generally, program modules comprise routines, programs, components, data structures, etc., that perform particular tasks or implement particular abstract data types. Moreover, those skilled in the art will appreciate that the methods can be practiced with other computer system configurations, comprising single-processor or multiprocessor computer systems, minicomputers, mainframe computers, as well as personal computers, hand-held computing devices, microprocessor-based or programmable consumer electronics, and the like, each of which can be operatively coupled to one or more associated devices.

As used herein, a processing circuit includes one or more processors as well as other application specific circuits such as an application specific integrated circuit, digital logic circuit, state machine, programmable gate array or other circuit that processes input signals or data and that produces output signals or data in response thereto. It should be noted that any functions and features described herein in association with the operation of a processor could likewise be performed by a processing circuit.

The illustrated embodiments of the embodiments herein can be also practiced in distributed computing environments where certain tasks are performed by remote processing devices that are linked through a communications network. In a distributed computing environment, program modules can be located in both local and remote memory storage devices.

Computing devices typically comprise a variety of media, which can comprise computer-readable storage media and/or communications media, which two terms are used herein differently from one another as follows. Computer-readable storage media can be any available storage media that can be accessed by the computer and comprises both volatile and nonvolatile media, removable and non-removable media. By way of example, and not limitation, computer-readable storage media can be implemented in connection with any method or technology for storage of information such as computer-readable instructions, program modules, structured data or unstructured data.

Computer-readable storage media can comprise, but are not limited to, random access memory (RAM), read only memory (ROM), electrically erasable programmable read only memory (EEPROM), flash memory or other memory technology, compact disk read only memory (CD ROM), digital versatile disk (DVD) or other optical disk storage, magnetic cassettes, magnetic tape, magnetic disk storage or other magnetic storage devices or other tangible and/or non-transitory media which can be used to store desired information. In this regard, the terms “tangible” or “non-transitory” herein as applied to storage, memory or computer-readable media, are to be understood to exclude only propagating transitory signals per se as modifiers and do not relinquish rights to all standard storage, memory or computer-readable media that are not only propagating transitory signals per se.

Computer-readable storage media can be accessed by one or more local or remote computing devices, e.g., via access requests, queries or other data retrieval protocols, for a variety of operations with respect to the information stored by the medium.

Communications media typically embody computer-readable instructions, data structures, program modules or other structured or unstructured data in a data signal such as a modulated data signal, e.g., a carrier wave or other transport mechanism, and comprises any information delivery or transport media. The term “modulated data signal” or signals refers to a signal that has one or more of its characteristics set or changed in such a manner as to encode information in one or more signals. By way of example, and not limitation, communication media comprise wired media, such as a wired network or direct-wired connection, and wireless media such as acoustic, RF, infrared and other wireless media.

With reference again to FIG. 4, the example environment can comprise a computer 402, the computer 402 comprising a processing unit 404, a system memory 406 and a system bus 408. The system bus 408 couples system components including, but not limited to, the system memory 406 to the processing unit 404. The processing unit 404 can be any of various commercially available processors. Dual microprocessors and other multiprocessor architectures can also be employed as the processing unit 404.

The system bus 408 can be any of several types of bus structure that can further interconnect to a memory bus (with or without a memory controller), a peripheral bus, and a local bus using any of a variety of commercially available bus architectures. The system memory 406 comprises ROM 410 and RAM 412. A basic input/output system (BIOS) can be stored in a non-volatile memory such as ROM, erasable programmable read only memory (EPROM), EEPROM, which BIOS contains the basic routines that help to transfer information between elements within the computer 402, such as during startup. The RAM 412 can also comprise a high-speed RAM such as static RAM for caching data.

The computer 402 further comprises an internal hard disk drive (HDD) 414 (e.g., EIDE, SATA), which internal HDD 414 can also be configured for external use in a suitable chassis (not shown), a magnetic floppy disk drive (FDD) 416, (e.g., to read from or write to a removable diskette 418) and an optical disk drive 420, (e.g., reading a CD-ROM disk 422 or, to read from or write to other high-capacity optical media such as the DVD). The HDD 414, magnetic FDD 416 and optical disk drive 420 can be connected to the system bus 408 by a hard disk drive interface 424, a magnetic disk drive interface 426 and an optical drive interface 428, respectively. The hard disk drive interface 424 for external drive implementations comprises at least one or both of Universal Serial Bus (USB) and Institute of Electrical and Electronics Engineers (IEEE) 1394 interface technologies. Other external drive connection technologies are within contemplation of the embodiments described herein.

The drives and their associated computer-readable storage media provide nonvolatile storage of data, data structures, computer-executable instructions, and so forth. For the computer 402, the drives and storage media accommodate the storage of any data in a suitable digital format. Although the description of computer-readable storage media above refers to a hard disk drive (HDD), a removable magnetic diskette, and a removable optical media such as a CD or DVD, it should be appreciated by those skilled in the art that other types of storage media which are readable by a computer, such as zip drives, magnetic cassettes, flash memory cards, cartridges, and the like, can also be used in the example operating environment, and further, that any such storage media can contain computer-executable instructions for performing the methods described herein.

A number of program modules can be stored in the drives and RAM 412, comprising an operating system 430, one or more application programs 432, other program modules 434 and program data 436. All or portions of the operating system, applications, modules, and/or data can also be cached in the RAM 412. The systems and methods described herein can be implemented utilizing various commercially available operating systems or combinations of operating systems.

A user can enter commands and information into the computer 402 through one or more wired/wireless input devices, e.g., a keyboard 438 and a pointing device, such as a mouse 440. Other input devices (not shown) can comprise a microphone, an infrared (IR) remote control, a joystick, a game pad, a stylus pen, touch screen or the like. These and other input devices are often connected to the processing unit 404 through an input device interface 442 that can be coupled to the system bus 408, but can be connected by other interfaces, such as a parallel port, an IEEE 1394 serial port, a game port, a universal serial bus (USB) port, an IR interface, etc.

A monitor 444 or other type of display device can be also connected to the system bus 408 via an interface, such as a video adapter 446. It will also be appreciated that in alternative embodiments, a monitor 444 can also be any display device (e.g., another computer having a display, a smart phone, a tablet computer, etc.) for receiving display information associated with computer 402 via any means of communication, including via the Internet and cloud-based networks. In addition to monitor 444, a computer typically comprises other peripheral output devices (not shown), such as speakers, printers, etc.

The computer 402 can operate in a networked environment using logical connections via wired and/or wireless communications to one or more remote computers, such as a remote computer(s) 448. The remote computer(s) 448 can be a workstation, a server computer, a router, a personal computer, portable computer, microprocessor-based entertainment appliance, a peer device or other common network node, and typically comprises many or all of the elements described relative to the computer 402, although, for purposes of brevity, only a remote memory/storage device 450 is illustrated. The logical connections depicted comprise wired/wireless connectivity to a local area network (LAN) 452 and/or larger networks, e.g., a wide area network (WAN) 454. Such LAN and WAN networking environments are commonplace in offices and companies, and facilitate enterprise-wide computer networks, such as intranets, all of which can connect to a global communications network, e.g., the Internet.

When used in a LAN networking environment, the computer 402 can be connected to the LAN 452 through a wired and/or wireless communication network interface or adapter 456. The adapter 456 can facilitate wired or wireless communication to the LAN 452, which can also comprise a wireless AP disposed thereon for communicating with the adapter 456.

When used in a WAN networking environment, the computer 402 can comprise a modem 458 or can be connected to a communications server on the WAN 454 or has other means for establishing communications over the WAN 454, such as by way of the Internet. The modem 458, which can be internal or external and a wired or wireless device, can be connected to the system bus 408 via the input device interface 442. In a networked environment, program modules depicted relative to the computer 402 or portions thereof, can be stored in the remote memory/storage device 450. It will be appreciated that the network connections shown are examples and other means of establishing a communications link between the computers can be used.

The computer 402 can be operable to communicate with any wireless devices or entities operatively disposed in wireless communication, e.g., a printer, scanner, desktop and/or portable computer, portable data assistant, communications satellite, any piece of equipment or location associated with a wirelessly detectable tag (e.g., a kiosk, news stand, restroom), and telephone. This can comprise Wireless Fidelity (Wi-Fi) and BLUETOOTH® wireless technologies. Thus, the communication can be a predefined structure as with a conventional network or simply an ad hoc communication between at least two devices.

Wi-Fi can allow connection to the Internet from a couch at home, a bed in a hotel room or a conference room at work, without wires. Wi-Fi is a wireless technology similar to that used in a cell phone that enables such devices, e.g., computers, to send and receive data indoors and out; anywhere within the range of a base station. Wi-Fi networks use radio technologies called IEEE 802.11 (a, b, g, n, ac, ag, etc.) to provide secure, reliable, fast wireless connectivity. A Wi-Fi network can be used to connect computers to each other, to the Internet, and to wired networks (which can use IEEE 802.3 or Ethernet). Wi-Fi networks operate in the unlicensed 2.4 and 5 GHz radio bands for example or with products that contain both bands (dual band), so the networks can provide real-world performance similar to the basic 10BaseT wired Ethernet networks used in many offices.

What has been described above includes mere examples of various embodiments. It is, of course, not possible to describe every conceivable combination of components or methodologies for purposes of describing these examples, but one of ordinary skill in the art can recognize that many further combinations and permutations of the present embodiments are possible. Accordingly, the embodiments disclosed and/or claimed herein are intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

Computing devices typically comprise a variety of media, which can comprise computer-readable storage media and/or communications media, which two terms are used herein differently from one another as follows. Computer-readable storage media can be any available storage media that can be accessed by the computer and comprises both volatile and nonvolatile media, removable and non-removable media. By way of example, and not limitation, computer-readable storage media can be implemented in connection with any method or technology for storage of information such as computer-readable instructions, program modules, structured data or unstructured data. Computer-readable storage media can comprise the widest variety of storage media including tangible and/or non-transitory media which can be used to store desired information. In this regard, the terms “tangible” or “non-transitory” herein as applied to storage, memory or computer-readable media, are to be understood to exclude only propagating transitory signals per se as modifiers and do not relinquish rights to all standard storage, memory or computer-readable media that are not only propagating transitory signals per se.

In addition, a flow diagram may include a “start” and/or “continue” indication. The “start” and “continue” indications reflect that the steps presented can optionally be incorporated in or otherwise used in conjunction with other routines. In this context, “start” indicates the beginning of the first step presented and may be preceded by other activities not specifically shown. Further, the “continue” indication reflects that the steps presented may be performed multiple times and/or may be succeeded by other activities not specifically shown. Further, while a flow diagram indicates a particular ordering of steps, other orderings are likewise possible provided that the principles of causality are maintained.

As may also be used herein, the term(s) “operably coupled to”, “coupled to”, and/or “coupling” includes direct coupling between items and/or indirect coupling between items via one or more intervening items. Such items and intervening items include, but are not limited to, junctions, communication paths, components, circuit elements, circuits, functional blocks, and/or devices. As an example of indirect coupling, a signal conveyed from a first item to a second item may be modified by one or more intervening items by modifying the form, nature or format of information in a signal, while one or more elements of the information in the signal are nevertheless conveyed in a manner that can be recognized by the second item. In a further example of indirect coupling, an action in a first item can cause a reaction on the second item, as a result of actions and/or reactions in one or more intervening items.

Although specific embodiments have been illustrated and described herein, it should be appreciated that any arrangement which achieves the same or similar purpose may be substituted for the embodiments described or shown by the subject disclosure. The subject disclosure is intended to cover any and all adaptations or variations of various embodiments. Combinations of the above embodiments, and other embodiments not specifically described herein, can be used in the subject disclosure. For instance, one or more features from one or more embodiments can be combined with one or more features of one or more other embodiments. In one or more embodiments, features that are positively recited can also be negatively recited and excluded from the embodiment with or without replacement by another structural and/or functional feature. The steps or functions described with respect to the embodiments of the subject disclosure can be performed in any order. The steps or functions described with respect to the embodiments of the subject disclosure can be performed alone or in combination with other steps or functions of the subject disclosure, as well as from other embodiments or from other steps that have not been described in the subject disclosure. Further, more than or less than all of the features described with respect to an embodiment can also be utilized.

What is claimed is:

1. A system comprising:
a processing system including a processor; and
a memory that stores executable instructions that, when executed by the processing system, facilitate performance of operations, the operations comprising:
developing code in a first environment for verifying hardware in a second environment;
modifying the code via at least one socket to transform the code to a register-transfer level (RTL) model description; and
simulating, using the RTL model description, the functionality of the hardware in the second environment without the hardware being physically present in the second environment, resulting in a first simulation.

2. The system of claim 1, wherein the developing of the code in the first environment comprises developing the code in MATLAB.

3. The system of claim 1, wherein the second environment adheres to the Universal Verification Methodology (UVM).

4. The system of claim 1, wherein the hardware is modeled via analog models in the second environment, and wherein the simulating comprises simulating the analog models.

5. The system of claim 4, wherein the hardware is modeled via digital models in the second environment, and wherein the simulating comprises simulating the digital models.

6. The system of claim 1, wherein the first environment is executed on a first machine and the second environment is executed on a second machine that is different from the first machine.

7. The system of claim 6, wherein the first machine includes a personal or desktop computer.

8. The system of claim 7, wherein the second machine includes a server.

9. The system of claim 1, wherein the operations further comprise:
subsequent to the first simulation, modifying the code in the first environment, resulting in second code; and
modifying the second code via the at least one socket to transform the second code to a second register-transfer level (RTL) model description; and
simulating, using the second RTL model description, the functionality of the hardware in the second environment without the hardware being physically present in the second environment, resulting in a second simulation that is different from the first simulation.

10. The system of claim 9, wherein the simulating utilizes a simulator, and wherein the simulator is compiled prior to the first simulation.

11. The system of claim 10, wherein the simulator is not re-compiled prior to the second simulation.

12. The system of claim 1, wherein the at least one socket is operative in accordance with the Transmission Control Protocol (TCP), the Internet Protocol (IP), or a combination thereof.

13. The system of claim 12, wherein the operations further comprise:
subsequent to the first simulation, obtaining a tangible instance of the hardware;
modifying the code via a second at least one socket, resulting in modified code; and
testing the tangible instance of the hardware using the modified code.

14. The system of claim 13, wherein the second at least one socket is operative in accordance with the User Datagram Protocol (UDP).

15. A non-transitory machine-readable medium, comprising executable instructions that, when executed by a processing system including a processor, facilitate performance of operations, the operations comprising:
developing code in a first environment for verifying hardware in a second environment;
modifying the code via at least one socket to transform the code to a register-transfer level (RTL) model description; and
simulating, using the RTL model description, the functionality of the hardware in the second environment without the hardware being physically present in the second environment, resulting in a first simulation.

16. The non-transitory machine-readable medium of claim 15, wherein the developing of the code in the first environment comprises developing the code in MATLAB.

17. The non-transitory machine-readable medium of claim 15, wherein the second environment adheres to the Universal Verification Methodology (UVM).

18. The non-transitory machine-readable medium of claim 15, wherein the hardware is modeled via analog models and digital models in the second environment, and wherein the simulating comprises simulating the analog models and the digital models.

19. A method, comprising:
developing, by a processing system including a processor, code in a first environment for verifying hardware in a second environment;
modifying, by the processing system, the code via at least one socket to transform the code to a register-transfer level (RTL) model description; and
simulating, by the processing system and using the RTL model description, the functionality of the hardware in the second environment without the hardware being physically present in the second environment, resulting in a first simulation.

20. The method of claim 19, wherein the hardware corresponds to an application-specific integrated circuit (ASIC), and wherein the code configures a clock signal for simulating the functionality of the hardware in the second environment.
